(19) United States
(12) Patent Application Publication
(10) Pub. No.: US 2024/0224527 A1
(43) Pub. Date: Jul. 4, 2024

(54) MEMORY DEVICE BASED ON IGO CHANNEL LAYER AND METHOD OF FABRICATING THE SAME

(71) Applicant: Industry-University Cooperation Foundation Hanyang University, Seoul (KR)

(72) Inventors: Chang Hwan CHOI, Seoul (KR); Jae Kyeong JEONG, Seoul (KR); Soon Oh JEONG, Seoul (KR); Hoon Hee HAN, Seoul (KR); Xuan WANG, Seoul (KR); Hyeon Joo SEUL, Seoul (KR)

(73) Assignee: Industry-University Cooperation Foundation Hanyang University, Seoul (KR)

(21) Appl. No.: 18/609,871

(22) Filed: Mar. 19, 2024

Related U.S. Application Data
(62) Division of application No. 17/085,155, filed on Oct. 30, 2020.

(30) Foreign Application Priority Data
Feb. 17, 2019 (KR) 10-2019-0168964

(51) Int. Cl. H10B 43/27; H01L 21/02; H01L 29/04; H01L 29/24

(52) U.S. Cl. CPC H10B 43/27; H01L 21/02565; H01L 21/02609; H01L 21/0262; H01L 29/045; H01L 29/24

(57) ABSTRACT

Disclosed are a memory device based on an IGO channel layer and a method of fabricating the same. More particularly, the memory device according to an embodiment includes multilayers including at least one transition metal; and a channel layer formed adjacent to the multilayers and configured to include an indium gallium oxide (IGO) material.

### CROSS-REFERENCE TO RELATED APPLICATION

This application is a Divisional Application of U.S. application Ser. No. 17/085,155, filed Oct. 30, 2020, which claims the priority benefit of Korean Patent Application No. 10-2019-0168964, filed on Dec. 17, 2019, in the Korean Intellectual Property Office, the disclosures of which are incorporated herein by reference.

### BACKGROUND OF THE DISCLOSURE

### Field of the Disclosure

The present disclosure relates to a memory device and a method of fabricating the same, and more particularly to a technical idea of forming a channel layer using an IGO material.

### Description of the Related Art

2D NAND flash memory has limitations due to deterioration in cell characteristics, process and scaling, etc., so that 3D V-NAND flash memory based on Charge Trap Flash (CTF) has attracted attention in recent years.

The integration degree of 3D V-NAND flash memory can be improved by increasing the number of stages thereof. Recently, a 64-stage 512 Gb product has been successfully developed. As such, the industry aims to implement a highly-staged, highly-integrated memory.

However, 3D V-NAND flash memory exhibits problems due to cell-to-cell degradation characteristics in a polysilicon (Si) channel layer and low carrier mobility and uniformity.

More particularly, since 3D V-NAND flash memory uses polysilicon as a channel, current flows through a grain boundary. Accordingly, in the high-stage structure, a non-uniform threshold voltage occurs as the length of a channel increases, and there are problems regarding electrical characteristics due to low carrier mobility and a non-uniform polysilicon grain size. In addition, as the number of stacks increases, there are problems regarding filling after formation of holes, and the properties of polysilicon are deteriorated.

Accordingly, there is increasing need for development of a novel channel material that is capable of replacing an existing polysilicon channel layer and improving electrical characteristics.

### RELATED ART DOCUMENT

### Patent Document

Korean Patent Application Publication No. 10-2018-0033952, “THREE DIMENSIONAL FLASH MEMORY FOR INCREASING CELL CURRENT AND MANUFACTURING METHOD THEREOF”

### SUMMARY OF THE DISCLOSURE

Therefore, the present disclosure has been made in view of the above problems, and it is an object of the present disclosure to provide a memory device that includes a channel layer formed by depositing an IGO material through an atomic layer deposition method, and a method of fabricating the memory device. Accordingly, the size of the memory device can be reduced.

It is another object of the present disclosure to provide a memory device including a deposited IGO material that is crystallized through thermal treatment, and a method of fabricating the memory device. Accordingly, problems, such as long conductive paths and poor carrier mobility characteristics, due to non-uniform grain sizes exhibited in an existing polysilicon channel layer can be addressed.

In accordance with an aspect of the present disclosure, the above and other objects can be accomplished by the provision of a memory device, including: multilayers including at least one transition metal; and a channel layer formed adjacent to the multilayers and configured to include an indium gallium oxide (IGO) material.

In accordance with an aspect, the channel layer may include the IGO material crystallized through thermal treatment performed in a temperature range of 650 to 750.

In accordance with an aspect, the IGO material may be crystallized to have a (222) crystal plane.

In accordance with an aspect, the multilayers may be oxide-nitride-oxide (ONO) layers including a tunneling oxide layer, a charge trap layer and a blocking oxide layer.

In accordance with an aspect, the transition metal may include at least one of aluminum (Al), titanium (Ti) and titanium nitride (TiN).

In accordance with another aspect of the present disclosure, there is provided a method of fabricating a memory device, the method including: forming multilayers including at least one transition metal; and forming a channel layer to be adjacent to the multilayers and to include an indium gallium oxide (IGO) material.

In accordance with an aspect, in the forming of the channel layer, the IGO material may be crystallized through thermal treatment performed in a temperature range of 650 to 750.

In accordance with an aspect, the IGO material may be crystallized to have a (222) crystal plane.

In accordance with an aspect, in the forming of the channel layer, the IGO material may be deposited to a thickness of 10 nm to 20 nm through atomic layer deposition (ALD) to form the channel layer.

In accordance with an aspect, the multilayers may be oxide-nitride-oxide (ONO) layers including a tunneling oxide layer, a charge trap layer and a blocking oxide layer.

In accordance with an aspect, the transition metal may include at least one of aluminum (Al), titanium (Ti) and titanium nitride (TiN).

In accordance with an aspect, the method of fabricating the memory device according to an embodiment may further include alternately laminating a plurality of electrode layers and a plurality of interlayer insulating layers; and forming a hole to pass through the laminated electrode layers and interlayer insulating layers.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 illustrates a memory device according to an embodiment;

FIG. 2 illustrates a memory device according to another embodiment;

FIGS. 3A to 3D illustrates I-V characteristics of a memory device according to an embodiment;

FIG. 4 illustrates the crystallization property of a channel layer of a memory device according to an embodiment;

FIGS. 5A to 5C illustrates heat treatment temperature-dependent characteristics of a channel layer of a memory device according to an embodiment; and

FIGS. 6A to 6D illustrate a method of fabricating a memory device according to an embodiment.

### DETAILED DESCRIPTION OF THE DISCLOSURE

The present disclosure will now be described more fully with reference to the accompanying drawings, in which exemplary embodiments of the disclosure are shown.

This disclosure, however, should not be construed as limited to the exemplary embodiments and terms used in the exemplary embodiments, and should be understood as including various modifications, equivalents, and substituents of the exemplary embodiments.

Preferred embodiments of the present disclosure are now described more fully with reference to the accompanying drawings. In the description of embodiments of the present disclosure, certain detailed explanations of related known functions or constructions are omitted when it is deemed that they may unnecessarily obscure the essence of the disclosure.

In addition, the terms used in the specification are defined in consideration of functions used in the present disclosure, and can be changed according to the intent or conventionally used methods of clients, operators, and users. Accordingly, definitions of the terms should be understood on the basis of the entire description of the present specification.

In the drawings, like reference numerals in the drawings denote like elements.

As used herein, the singular forms “a,” “an” and “the” are intended to include the plural forms as well, unless context clearly indicates otherwise.

Expressions such as “A or B” and “at least one of A and/or B” should be understood to include all possible combinations of listed items.

Expressions such as “a first,” “the first,” “a second” and “the second” may qualify corresponding components irrespective of order or importance and may be only used to distinguish one component from another component without being limited to the corresponding components.

In the case in which a (e.g., first) component is referred as “(functionally or communicatively) connected” or “attached” to another (e.g., second) component, the first component may be directly connected to the second component or may be connected to the second component via another component (e.g., third component).

In the specification, the expression “ . . . configured to . . . (or set to)” may be used interchangeably, for example, with expressions, such as “ . . . suitable for . . . ,” “ . . . having ability to . . . ,” “ . . . modified to . . . ,” “ . . . manufactured to . . . ,” “ . . . enabling to . . . ,” or “ . . . designed to . . . ,” in the case of hardware or software depending upon situations.

In any situation, the expression “a device configured to . . . ” may refer to a device configured to operate “with another device or component.”

For examples, the expression “a processor configured (or set) to execute A, B, and C” may refer to a specific processor performing a corresponding operation (e.g., embedded processor), or a general-purpose processor (e.g., CPU or application processor) executing one or more software programs stored in a memory device to perform corresponding operations.

In addition, the expression “or” means “inclusive or” rather than “exclusive or”.

That is, unless otherwise mentioned or clearly inferred from context, the expression “x uses a or b” means any one of natural inclusive permutations.

In the aforementioned embodiments, constituents of the present disclosure were expressed in a singular or plural form depending upon embodiments thereof.

However, the singular or plural expressions should be understood to be suitably selected depending upon a suggested situation for convenience of description, and the aforementioned embodiments should be understood not to be limited to the disclosed singular or plural forms. In other words, it should be understood that plural constituents may be a singular constituent or a singular constituent may be plural constituents.

While the embodiments of the present disclosure have been described, those skilled in the art will appreciate that many modifications and changes can be made to the present disclosure without departing from the spirit and essential characteristics of the present disclosure.

Therefore, it should be understood that there is no intent to limit the disclosure to the embodiments disclosed, rather, the disclosure is to cover all modifications, equivalents, and alternatives falling within the spirit and scope of the disclosure as defined by the claims.

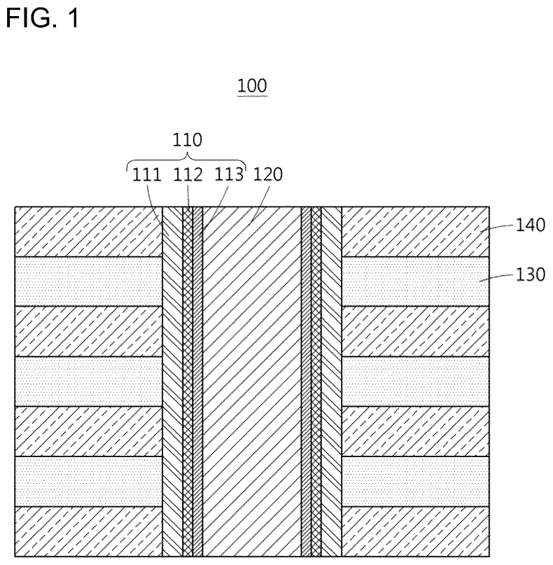

FIG. 1 illustrates a memory device according to an embodiment.

Referring to FIG. 1, the size of a memory device 100 according to an embodiment may be reduced by depositing an IGO material through an atomic layer deposition method to form a channel layer.

In addition, the deposited IGO material of the memory device 100 is crystallized through thermal treatment, so that problems, such as long conductive paths and low carrier mobility, due to non-uniform grain sizes exhibited in an existing polysilicon channel layer may be improved.

The memory device 100 described below with reference to FIG. 1 may be a 3D V-NAND flash memory device. In addition, the memory device 100 may be at least one of a 2D NAND flash memory, DRAM and SRAM in addition to a 3D V-NAND flash memory device.

Particularly, the memory device 100 may include a plurality of electrode layers 130, a plurality of interlayer insulating layers 140, multilayers 110 and a channel layer 120, wherein each of the plural electrode layers 130 may operate as a control gate.

More particularly, the plural electrode layers 130 and the plural interlayer insulating layers 140 may be laminated in a direction (horizontal direction) orthogonal to the channel layer 120 formed in a vertical direction, and the plural electrode layers 130 and the plural interlayer insulating layers 140 may be alternately disposed and extend in a horizontal direction.

Here, the plural interlayer insulating layers 140 may be a silicon oxide film or a silicon nitride film and may have the same ore different thicknesses. For example, the plural interlayer insulating layers 140 may be formed to have a thicker thickness toward the bottom.

The plural electrode layers 130 may be formed of a conductive material, and may have the same or different thicknesses as in the plural interlayer insulating layers 140.

The multilayers 110 according to an embodiment may include at least one transition metal. For example, the transition metal may include at least on of aluminum (Al), titanium (Ti) and titanium nitride (TiN), and may be formed to a thickness of 15 nm or more.

For example, the multilayers 110 may be an Oxide-Nitride-Oxide (ONO) layer including a tunneling oxide layer 113, a charge trap layer 112 and a blocking oxide layer 111. Here, the charge trap layer 112 may operate a floating gate.

More particularly, the tunneling oxide layer 113 may be formed adjacent to the channel layer 120, and the blocking oxide layer 111 may be formed adjacent to the plural electrode layers 130 and the plural interlayer insulating layers 140.

Preferably, the blocking oxide layer 111 may be formed of silicon oxide (SiO₂) material, the charge trap layer 112 may be formed of a silicon nitride (Si₃N₄) material, and the tunneling oxide layer 113 may be formed of an aluminum oxide (Al₂O₃) material.

The channel layer 120 according to an embodiment may be formed adjacent to the multilayers 110 and may include an indium gallium oxide (IGO) material.

For example, the channel layer 120 may be formed in a hollow tube shape. In this case, a filling layer for filling the inside of the channel layer 120 may be further included.

In addition, a drain region may be disposed on the channel layer 120, and a conductive pattern may be formed on the drain region to be connected to a bit line. In this case, the bit line may extend in a horizontal direction. Accordingly, when a plurality of channel layers 120 are included and are aligned in a horizontal direction, the plural channel layers may be connected to a common bit line.

In accordance with an aspect, an IGO material for forming the channel layer 120 may be deposited through atomic layer deposition (ALD). Here, the IGO material may be deposited to a thickness of 10 nm to 20 nm.

ALD, which is a deposition technology used to manufacture nano-scale semiconductor devices, can precisely control a very thin film, compared to existing thin-film deposition technologies such as a chemical vapor deposition and a physical vapor deposition method, and can manufacture a film having a low impurity content and almost no pinholes.

The principle of ALD is that, one atomic layer is deposited as each of reactants (precursors) separated by an inert gas (Ar, N₂, etc.) is supplied on a substrate, and the atomic layer may be repeatedly deposited to have a desired thickness.

That is, in the case of ALD, one reactant is chemically adsorbed, and then a second or third gas is introduced and chemical adsorption occurs again, unlike a chemical vapor deposition method where a reactive gas is deposited by vapor reaction, so that a thin film is formed.

In conclusion, the present disclosure uses ALD, thereby forming an IGO thin film having an atomic layer thickness and, accordingly, improved step coverage and a dense film.

In accordance with an aspect, the channel layer 120 may include an IGO material crystallized through thermal treatment performed in a temperature range of 650° C. to 750° C. Here, the IGO material may be crystallized to have a (222) crystal plane. Preferably, the IGO material may be crystallized through thermal treatment at 700° C.

In other words, the memory device 100 includes the IGO channel layer 120 crystallized to have a (202) crystal plane through thermal treatment performed in a temperature range of 650° C. to 750° C., thereby obtaining high mobility and memory window characteristics.

Meanwhile, the memory device 100 may further include a capping layer for covering an upper part of the channel layer 120 such that the channel layer 120 is not exposed to the outside.

More particularly, the capping layer may be formed of a conductive material, a conductor (e.g., group III-V compounds including Ga, As and P). In this case, a drain region, a conductive pattern of which is formed to be connected to a bit line, may be disposed at least on the capping layer. Accordingly, the channel layer 120 may be connected to a bit line though the capping layer that is a conductive material.

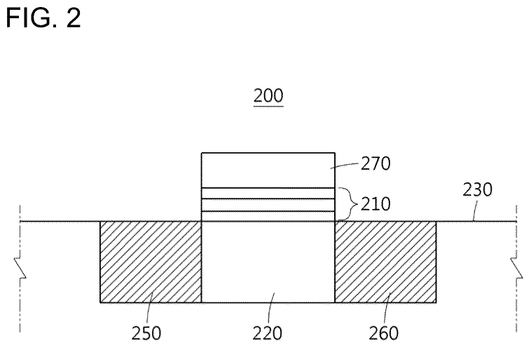

FIG. 2 illustrates a memory device according to another embodiment.

In other words, FIG. 2 illustrates another embodiment of the memory device described with reference to FIG. 1. Hereinafter, parts, which are the same as those described with reference to FIG. 1, of contents described with reference to FIG. 2 are omitted.

Referring to FIG. 2, a memory device 200 according to another embodiment may include a substrate 230, multilayers 210, a channel layer 220 and first to third electrodes 250 to 270.

For example, the substrate 230 may be a silicon single-crystal substrate, a germanium single-crystal substrate or a silicon-germanium single-crystal substrate or a Semiconductor on Insulator (SOI) substrate.

In addition, the substrate 230 may include a semiconductor layer (e.g., a silicon layer, a silicon-germanium layer or a germanium layer) that is disposed on an insulating layer for protecting an element (transistor, etc.) provided on a semiconductor substrate.

The memory device 200 described below with reference to FIG. 2 may be a 2D NAND flash memory device. The memory device 200 may include a plurality of memory elements including the multilayers 210, the channel layer 220 and the first to third electrodes 250 to 270.

In accordance with an aspect, the first electrode 250 may be a drain electrode, the second electrode 260 may be a source electrode, and the third electrode 270 may be a gate electrode. In addition, the first electrode 250 may be a source electrode, and the second electrode 260 may be a drain electrode.

Particularly, the multilayers 210 may include at least one transition metal. For example, the transition metal may include at least one of aluminum (Al), titanium (Ti) and titanium nitride (TiN).

In accordance with an aspect, the multilayers 210 may be an oxide-nitride-oxide (ONO) layer including a tunneling oxide layer, a charge trap layer and a blocking oxide layer.

The channel layer 220 according to an embodiment may be formed adjacent to the multilayers 210 and may include an indium gallium oxide (IGO) material. For example, the multilayers 210 may be formed on the channel layer 220.

In accordance with an aspect, the channel layer 120 may include an IGO material crystallized though thermal treatment performed in a temperature range of 650° C. to 750° C. Here, the IGO material may be crystallized to have a (222) crystal plane.

In addition, the IGO material for forming the channel layer 120 may be deposited through atomic layer deposition (ALD). Here, the IGO material may be deposited to a thickness of 10 nm to 20 nm.

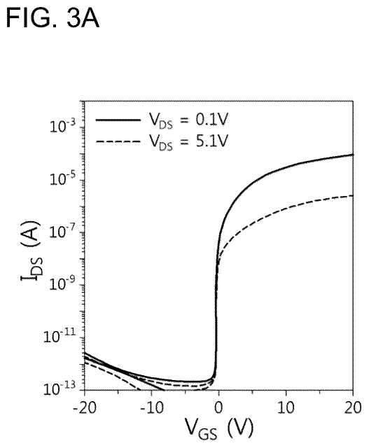

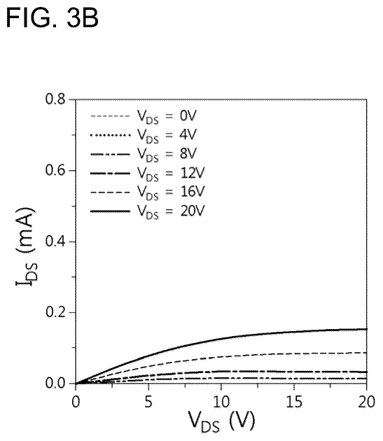

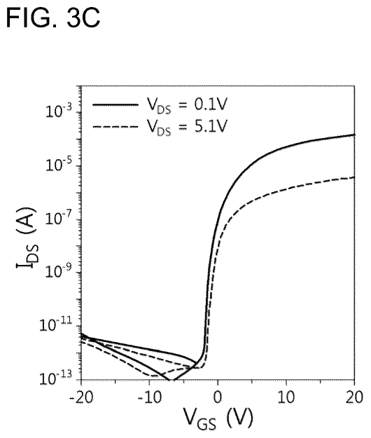

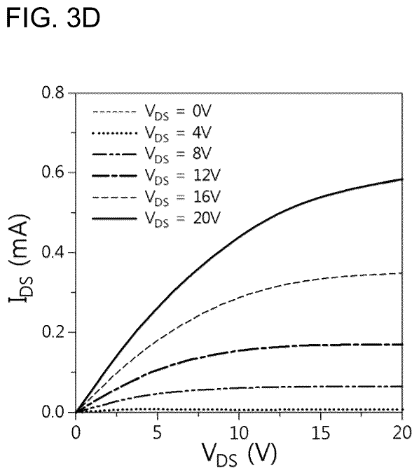

FIGS. 3A to 3D illustrates I-V characteristics of a memory device according to an embodiment.

Referring to FIGS. 3A to 3D, FIGS. 3A and 3B illustrate drain current (IDS)-gate voltage (VGS) and drain current (IDS)-drain voltage (VDS) characteristics of an IGO channel layer formed through a sputtering method, and FIGS. 3C and 3D illustrate drain current (IDS)-gate voltage (VGS) and drain current (IDS)-drain voltage (VDS) characteristics of an IGO channel layer formed through ALD.

Particularly, FIGS. 3A to 3D illustrate I-V characteristic comparison results of a Thin Film Transistor (TFT) element including the IGO channel layer of the memory device according to an embodiment.

As shown in FIGS. 3A to 3D, an IGO channel layer formed through ALD exhibits higher mobility than an IGO channel layer formed through a sputtering method. That is, it can be confirmed that excellent electrical characteristics are exhibited when an IGO channel layer applied to an NAND flash memory is deposited through ALD.

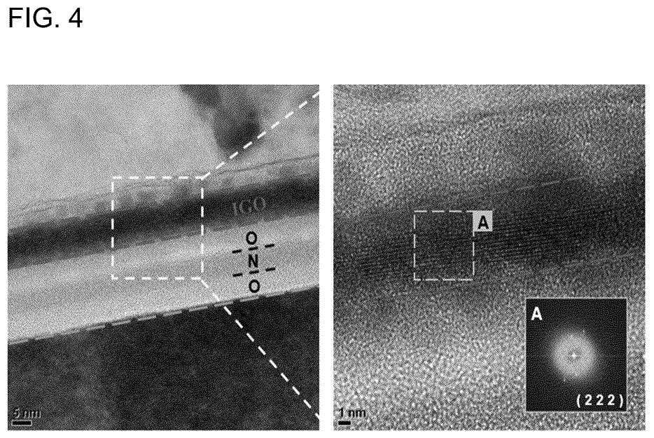

FIG. 4 illustrates the crystallization property of a channel layer of a memory device according to an embodiment.

Referring to FIG. 4, when an IGO channel layer according to an embodiment was thermally treated, and then observed through a transmission electron microscope (TEM), an IGO material was observed as being crystallized to have a (222) crystal plane.

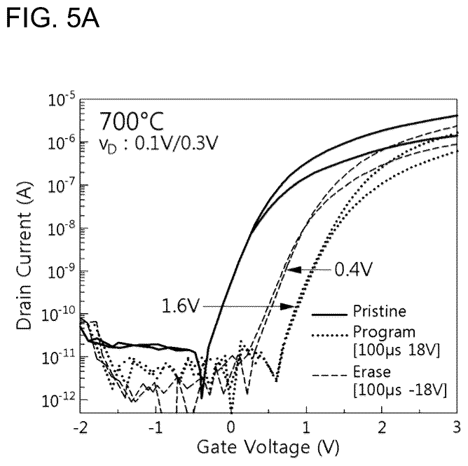

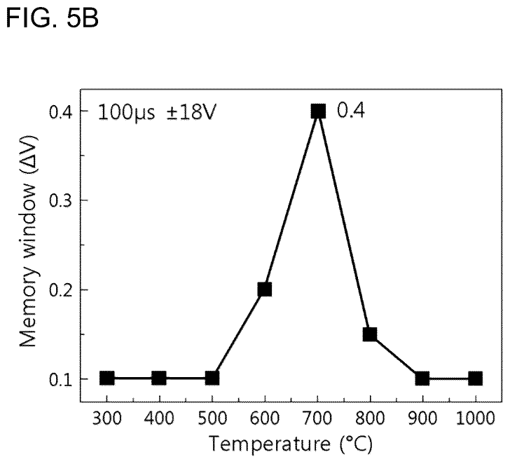

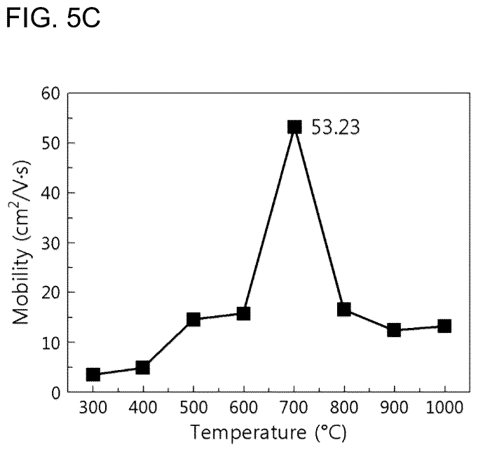

FIGS. 5A to 5C illustrates heat treatment temperature-dependent characteristics of a channel layer of a memory device according to an embodiment.

Referring to FIGS. 5A to 5C, FIG. 5A illustrates drain current-gate voltage (I-V) characteristics of an IGO channel thermally treated at 700° C., FIG. 5B illustrates a memory window characteristic dependent upon a heat treatment temperature, and FIG. 5C illustrates a mobility characteristic dependent upon a heat treatment temperature.

As shown in FIGS. 5A to 5C, after an IGO channel layer was deposited on an ONO layer, and then thermal treatment was performed at different temperatures (300° C. to 1,000° C.), electrical characteristics of a channel layer dependent upon thermal treatment were examined at a program pulse of 18V, 100 μs. It can be confirmed that a memory window of 0.3 V or higher and a mobility of 30 cm²/Vs or higher are obtained in the IGO channel layer thermally treated at 650° C. to 750° C.

In other words, it can be confirmed that a grain size of the IGO channel layer according to an embodiment increases and grain boundaries thereof are reduced, due to crystallization according to the thermal treatment, so that mobility is improved. In particular, when the IGO channel layer was thermally treated in a temperature range of 650° C. to 750° C., crystallization proceeded to have a (222) crystal plane, so that high mobility and memory window characteristics were exhibited.

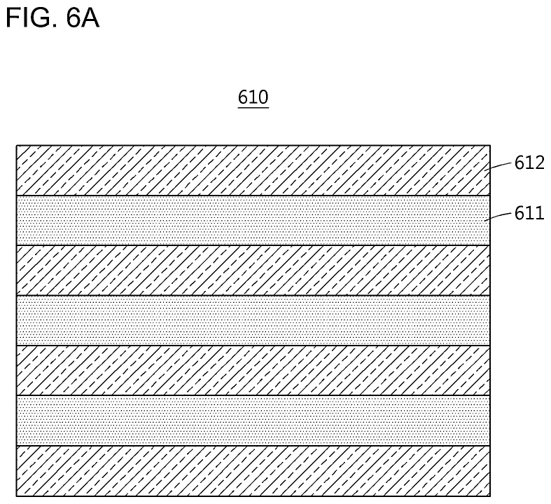

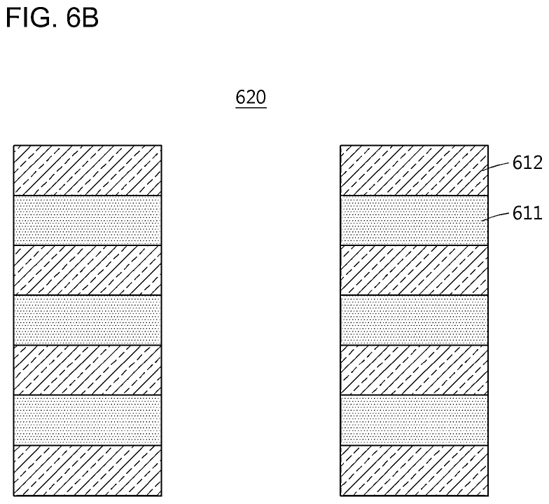

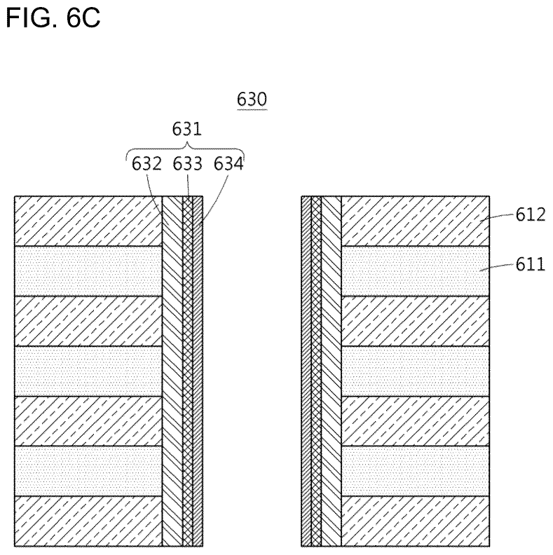

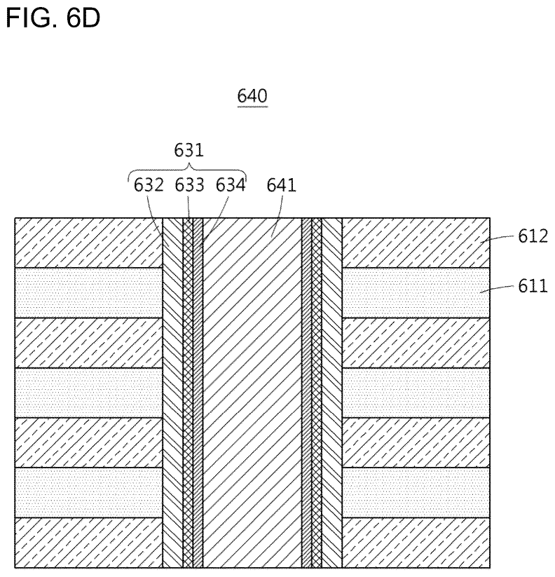

FIGS. 6A to 6D illustrate a method of fabricating a memory device according to an embodiment.

In other words, FIGS. 6A to 6D illustrate a method of fabricating the memory device according to an embodiment described with reference to FIGS. 1 to 5C. Hereinafter, parts, which are the same as those described with reference to FIGS. 1 to 5C, of contents described with reference to FIGS. 6a to 6d are omitted.

Referring to FIGS. 6A to 6D, in step 610 of the method of fabricating the memory device according to an embodiment, a plurality of an electrode layer 611 and a plurality of interlayer insulating layers 612 may be alternately laminated.

Next, in step 620 of the method of fabricating the memory device according to an embodiment, a hole may be formed to pass through the laminated plural electrode layers 611 and plural interlayer insulating layers 612.

Next, in step 630 of the method of fabricating the memory device according to an embodiment, multilayers 631 including at least one transition metal may be formed. For example, the transition metal may include at least one of aluminum (Al), titanium (Ti) and titanium nitride (TiN) and may be formed to a thickness of 15 nm or more.

In accordance with an aspect, the multilayers 631 may be an oxide-nitride-oxide (ONO) layer including a tunneling oxide layer 634, a charge trap layer 633 and a blocking oxide layer 632.

More particularly, in step 630 of the method of fabricating the memory device according to an embodiment, the blocking oxide layer 632 may be formed adjacent to the plural electrode layers 611 and the plural interlayer insulating layers 612, and the charge trap layer 633 may be formed adjacent to the formed blocking oxide layer 632, and then the tunneling oxide layer 634 may be formed on the charge trap layer 633.

Next, in step 640 of the method of fabricating the memory device according to an embodiment, a channel layer 641 including an indium gallium oxide (IGO) material may be formed adjacent to the multilayers 631.

In accordance with an aspect, in step 640 of the method of fabricating the memory device according to an embodiment, an IGO material may be deposited to a thickness of 10 nm to 20 nm through ALD to form a channel layer 641.

In accordance with an aspect, in step 640 of the method of fabricating the memory device according to an embodiment, the IGO material may be crystallized through thermal treatment performed in a temperature range of 650° C. to 750° C. Here, the IGO material may be crystallized to have a (222) crystal plane. Preferably, the IGO material may be thermally treated at 700° C., thereby being crystallized.

In accordance with an embodiment, an IGO material is deposited through atomic layer deposition (ALD) to form a channel layer, so that the size of a memory device can be reduced.

In accordance with an embodiment, the deposited IGO material is crystallized through thermal treatment, so that problems, such as long conductive paths and poor carrier mobility characteristics, due to non-uniform grain sizes exhibited in an existing polysilicon channel layer can be addressed.

Although the present disclosure has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

| [Description of Symbols] | |
|---|---|
| 100: memory device | 110: multilayer |
| 111: blocking oxide layer | 112: charge trap layer |
| 113: tunneling oxide layer | 120: channel layer |
| 130: electrode layer | 140: interlayer insulating layer |

What is claimed is:

1. A memory device, comprising:
multilayers comprising at least one transition metal; and
a channel layer formed adjacent to the multilayers and configured to comprise an indium gallium oxide (IGO) material.

2. The memory device according to claim 1, wherein the channel layer comprises the IGO material crystallized through thermal treatment performed in a temperature range of 650 to 750.

3. The memory device according to claim 2, wherein the IGO material is crystallized to have a (222) crystal plane.

4. The memory device according to claim 1, wherein the multilayers are oxide-nitride-oxide (ONO) layers comprising a tunneling oxide layer, a charge trap layer and a blocking oxide layer.

5. The memory device according to claim 1, wherein the transition metal comprises at least one of aluminum (Al), titanium (Ti) and titanium nitride (TiN).
